(19) United States
(12) Patent Application Publication
(10) Pub. No.: US 2026/0293353 A1
(43) Pub. Date: Sep. 24, 2026

(54) INTEGRATED CIRCUIT DEVICE AND METHOD OF MANUFACTURING THE SAME

(71) Applicant: Taiwan Semiconductor Manufacturing Company, Ltd., Hsinchu (TW)

(72) Inventors: Hsing-Chih Lin, Tainan City (TW); Min-Feng Kao, Chiayi City (TW); Meng-Fang Hsu, Hsinchu City (TW); Sheng-Chan Li, Tainan City (TW); Sheng-Chau Chen, Tainan City (TW); Hsiu-Yun Yeh, Taoyuan City (TW)

(21) Appl. No.: 19/088,047

(22) Filed: Mar. 24, 2025

(51) Int. Cl. H10F 39/00; H01L 23/00; H01L 25/04

(52) U.S. Cl. CPC H10F 39/811; H10F 39/014; H10F 39/024; H10F 39/026; H10F 39/8053; H10F 39/8063; H10W 90/00; H10W 90/20; H10W 90/792

(57) ABSTRACT

Some embodiments relate to a method of fabricating an integrated circuit (IC) device, including forming, on a first substrate of a first IC die having one or more first dielectric layers disposed on a first side of the first substrate, a second dielectric layer on a second side of the first substrate, where one or more first conductive structures are disposed in the one or more first dielectric layers; performing a high-density-plasma (HDP) chemical vapor deposition (CVD) operation employing a combination of silane gas and oxygen gas to form a third dielectric layer on the second dielectric layer; forming a second conductive structure that extends from a side of the first IC die and through the first substrate; and bonding the first IC die to a second IC die to electrically couple one or more third conductive structures of the second IC die to the second conductive structure.

### BACKGROUND

In an increasing number of use cases for integrated circuit (IC) devices, the use of multiple-die IC devices has become increasingly important for providing reduced device footprint, higher operating speeds, and the like. Further, when such technology is implemented in some imaging IC devices (e.g., complementary metal-oxide-semiconductor (CMOS) image sensor (CIS) devices), various image-related characteristics, such as image resolution, frame rate, and so on, may be positively impacted by the use of multiple IC dies bonded together within a single IC device.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 illustrates a cross-sectional view of some embodiments of an IC image device including multiple IC dies bonded together.

FIG. 2 illustrates a cross-sectional view of some embodiments of a magnified portion of the cross-sectional view of FIG. 1, including a multiple-layer dielectric structure disposed on a lower side of a substrate.

FIG. 3 illustrates a cross-sectional view depicting thicknesses of some embodiments of a subset of dielectric layers shown in FIG. 2.

FIGS. 4A through 4X illustrate cross-sectional views of some embodiments of a multiple-die IC imaging device associated with FIG. 1 in various stages of manufacture, according to the present disclosure.

FIGS. 5 and 6 illustrate methodologies of forming a multiple-die IC device, in accordance with some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

In some complementary metal-oxide-semiconductor (CMOS) image sensor (CIS) integrated circuit (IC) devices, multiple IC dies (e.g., three or more IC dies) may be bonded together to support several different circuits, components, or functions associated with an electronic device (e.g., a digital camera). For example, the multiple IC dies may include an array of photodetectors, timing and reading circuitry to convert charge stored in the photodetector to image data, data storage and/or processing circuitry to store and/or process the image data for use by other portions of the electronic device, and the like.

In such IC devices that employ three or more IC dies, the one or more interior dies may be bonded to two other IC dies at opposing sides of the interior die: one on a first side of the interior die at which a number of conductive (e.g., metal) layers located within several dielectric layers are disposed on an upper side of the substrate, and another on a second side of the interior die more closely coupled with a lower side of the substrate. While die bonding at a dielectric layer at the first side of the interior die with a dielectric layer of another IC die is generally believed to result in a stable connection between the dies, bonding at the lower side of the substrate at the second side of the interior die with a dielectric layer of another IC die sometimes results in a less stable IC device structure.

As is described in greater detail below, depending on the particular chemical properties of one or more dielectric materials disposed on the lower side of the substrate, at least a portion of the structure including the substrate and the dielectric layers disposed at the lower side of the substrate may ultimately delaminate. For example, the dielectric layer disposed on the lower side of the substrate may separate from the substrate itself. In some cases, it is suspected that one or more of the dielectric layers may outgas water vapor, causing the water vapor to build up at the lower side of the substrate, thus causing the delamination, thus damaging the IC device.

To address this issue, the present disclosure provides some embodiments of an IC device that produces a low level of water and/or incorporates a low amount of nitrogen in the one or more dielectric layers disposed on the lower side of the substrate. In some examples, nitrogen may operate to repel water, thus potentially urging at least some of the water present toward the lower side of the substrate, thereby possibly promoting delamination. In some embodiments, the amount of water present at or near the substrate (e.g., at or near one or more dielectric layers disposed on the lower side of the substrate) to be less than or equal to approximately 2×10⁻⁹ parts per million (ppm). Further, in some embodiments, the amount of nitrogen present may be less than five percent of what may normally be found in other dielectric layers employed in IC dies, such as inter-metal dielectric (IMD) layers deposited on a substrate, or dielectric layers used for bonding a substrate of a IC die to another IC die.

For example, a layer of undoped silicate glass (USG) that is deposited on an intervening dielectric layer (e.g., a high-kappa, or high-k, dielectric layer) that is disposed on a substrate may result in the presence of a significant amount of both water and nitrogen, possibly resulting in separation of the intervening dielectric layer from the substrate. In some examples, the USG may be formed by way of a high-density-plasma (HDP) chemical vapor deposition (CVD) operation using a combination of silane (SiH₄) gas and nitrous oxide (N₂O) gas (e.g., at a temperature of approximately 400 degrees Celsius).

In contrast, use of a layer of an HDP oxide deposited on an intervening dielectric layer (e.g., a high-k dielectric layer) that is disposed on the substrate may result in the presence of significantly less of both water (e.g., approximately 2×10⁻⁹ ppm) and nitrogen (e.g., a nitrogen concentration less than five percent of that provided in the USG case above, or less than five percent of a dielectric layer employed for inter-die bonding or for IMD layers disposed on a substrate), resulting in reducing or eliminating the potential for delamination at the substrate/intervening dielectric layer boundary. In some examples, the HDP oxide may be formed by way of an HDP CVD operation using a combination of silane (SiH₄) gas and oxygen (O₂) gas at a comparatively lower temperature (e.g., approximately 300 degrees Celsius) relative to the USG case described above.

In yet other embodiments, similar goals regarding reduced water and nitrogen levels may be attained in other ways. For example, the amount of water produced may be reduced by way of lowering the amount of film deposition precursor material (e.g., by lowering the amount or flow rate of silane gas and/or nitrous oxide gas employed to deposit a dielectric film). In other embodiments, the amount of nitrogen present may be reduced by way of extending the amount of exposure time, or reducing the power utilized, for the radio frequency (RF) energy used to create the high-density plasma from the precursor material being employed to create the film, which may result in reducing the nitrogen impurity being introduced into the deposited film.

Thus, in some embodiments, the reduced water and/or nitrogen present may result in the formation of a low-stress, high-adhesion dielectric film by reducing the possibility of delamination (e.g., between the substrate and the adjacent dielectric layer), thereby potentially resulting in a higher film stack quality and increased circuit probe (CP) testing yields.

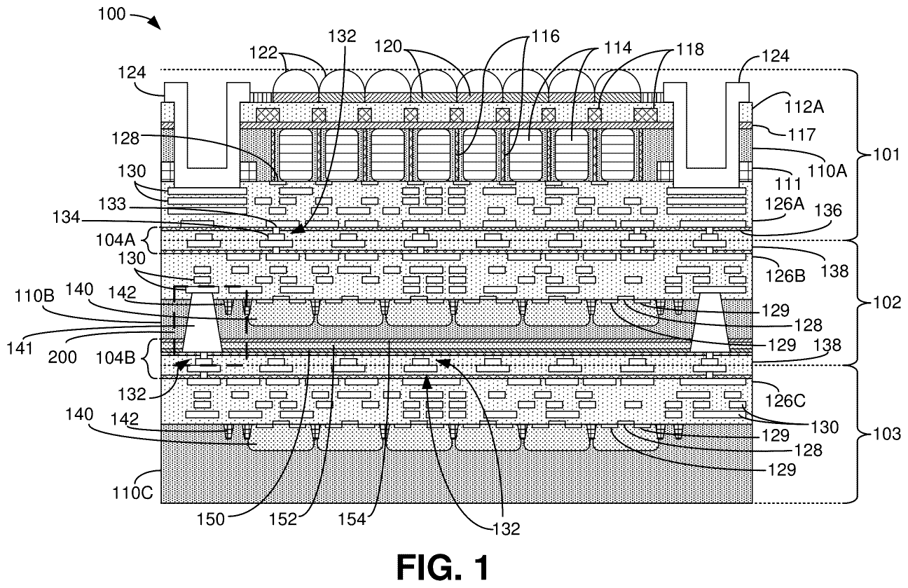

FIG. 1 illustrates a cross-sectional view of some embodiments of an IC image device (or, more generally, IC device) 100 including multiple IC dies (and/or wafers) 101, 102, and 103 bonded together. In the various embodiments described herein, IC die 102 is referred to at times as the first IC die, IC die 103 is sometimes referred to as the second IC die, and IC die 101 is referred to as the third IC die. Despite these ordinal labels, IC dies 101, 102, and 103 may be fabricated individually, and subsequently bonded to another of IC dies 101, 102, and 103, in any order, including concurrently. Additionally, while three IC dies 101, 102, and 103 are depicted in FIG. 1, two or more additional dies may be included in IC device 100 in other embodiments.

As shown in FIG. 1, IC die 101 includes a substrate 110A (e.g., a semiconductor substrate, such as a silicon (Si) substrate) in which a plurality of photosensitive regions 114 are disposed (e.g., doped or implanted within substrate 101A). In some embodiments, substrate 110A may be a p-type substrate and photosensitive regions 114 may be n-doped regions, or vice-versa. In some embodiments, each photosensitive region 114 may form part of a photodetector (e.g., a PN photodiode, a PIN photodiode, or the like) with a surrounding region of substrate 110A. While eight photosensitive regions 114 are depicted in FIG. 1, any other number of photosensitive regions 114 may be included in other embodiments.

In some embodiments, photosensitive regions 114 may be at least partially surrounded laterally by one or more vertically oriented optical isolation structures 116 that may extend at least partially into substrate 110A by way of an upper side thereof. Optical isolation structures 116 (e.g., fashioned as deep trench isolation (DTI) structures) may include a light-reflective material that may include one or more metals and/or one or more oxides (e.g., silicon oxide (SiOₓ), such as silicon dioxide (SiO₂), or another oxide) or other dielectric materials.

Also, in some embodiments, dielectric isolation structures 111 may be disposed in substrate 110A and may serve to electrically isolate a portion of a corresponding upper bond structure 124 from substrate 110A. In some embodiments, upper bond structure 124 may facilitate bonding with other IC device-related structures positioned over IC die 101.

Further, in some embodiments, disposed on substrate 110A may be one or more dielectric layers 117 and 112A, which may include, but are not limited to, silicon dioxide (SiO₂), another silicon oxide (SiOₓ), or another dielectric material. In some embodiments, dielectric layers 117 and 112A may be employed as a passivation layer and/or an anti-reflective coating (ARC) layer. Dielectric layers 117 and 112A may include one or more of silicon-oxide-aluminum (SiOAl), aluminum-oxide (AlO), hafnium-oxide (HfO), tatantalum-oxide-silicon (TaOSi) (e.g., for anti-reflection) and/or silicon oxide (SiOₓ) (e.g., for passivation).

Additionally, in some embodiments, a grid structure including one or more reflective segments 118 may be disposed over and/or in dielectric layers 117. Reflective segments 118 constituting the grid structure may define a plurality of openings through which light from above may be directed by reflective segments 118 toward photosensitive regions 114. In some embodiments, reflective segments 118 may include one or more materials, such as a metal (e.g., tungsten (W)), a barrier material (e.g., titanium nitride (TiN)), and/or a dielectric material (e.g., silicon oxide (SiOₓ).

In some embodiments, an optical filter layer having a plurality of filter elements 120 (e.g., where each filter element 120 may be disposed over a corresponding photosensitive region 114) may be disposed over dielectric layer 112A. Each filter element 120 may be include dielectric material that filters one or more wavelength bands of light to allow a particular wavelength band (e.g., a band that includes red, green, or blue) to pass therethrough. In some embodiments, each filter element 120 may include a pigment, dye, or other light-transmissive material that filters one or more wavelength bands of light.

Over filter elements 120, a corresponding plurality of lenses (e.g., microlenses) 122 may be disposed. Each lens 122 may be associated with a corresponding photosensitive region 114. In some embodiments, each lens 122 may direct at least some light through a corresponding filter element 120 and dielectric layers 112A and 117 into the corresponding photosensitive region 114 thereunder. In some embodiments, lenses 122 may be fabricated from a polymer, an oxide (e.g., silicon dioxide (SiO₂)), or other substantially transparent material.

In the view provided in FIG. 1, a plurality of gate structures 128 (e.g., one gate structure per photosensitive region 114) may be disposed on a lower side of substrate 110A to serve as a gate terminal for a transfer transistor that transfers electrical charge from photosensitive region 114 to a floating diffusion region (not explicitly shown in FIG. 1) for signal amplification, readout, and so on. In some embodiments, gate structures 128 may include polycrystalline silicon (poly-Si) or another conductive material disposed over an oxide or other dielectric material.

Also disposed on a lower side of substrate 110A are one or more dielectric layers 126A, within which one or more conductive structures 130 are disposed to facilitate electrical connections between circuit portions within IC die 101, as well as with adjacent IC die 102. In some embodiments, dielectric layers 126A may include, but are not limited to, silicon oxide (SiOₓ) (e.g., silicon oxide (SiO₂)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like. Conductive structures 130 may be arranged as layers of conductive elements (as illustrated in FIG. 1) selectively interconnected with conductive via structures (not explicitly shown in FIG. 1). In some embodiments, conductive structures 130 may include one or more of a metal (e.g., copper (Cu)), an alloy, or another conductive material (e.g., polycrystalline silicon (poly-Si)). One or more such conductive structure 130 may be electrically connected to one or more of gate structures 128.

To facilitate bonding and electrical connectivity with IC die 102, one or more dielectric layers 138 may be disposed on dielectric layers 126A, with one or more conductive bonding structures 132 being disposed therein. In some embodiments, conductive bonding structure 132 may include a bonding element 134 disposed at a lower side of IC die 101. Also, in some embodiments, conductive bonding structure 132 may further include a bonding via element 133 that electrically couples bonding element 134 to one or more conductive structures 130 of IC die 101.

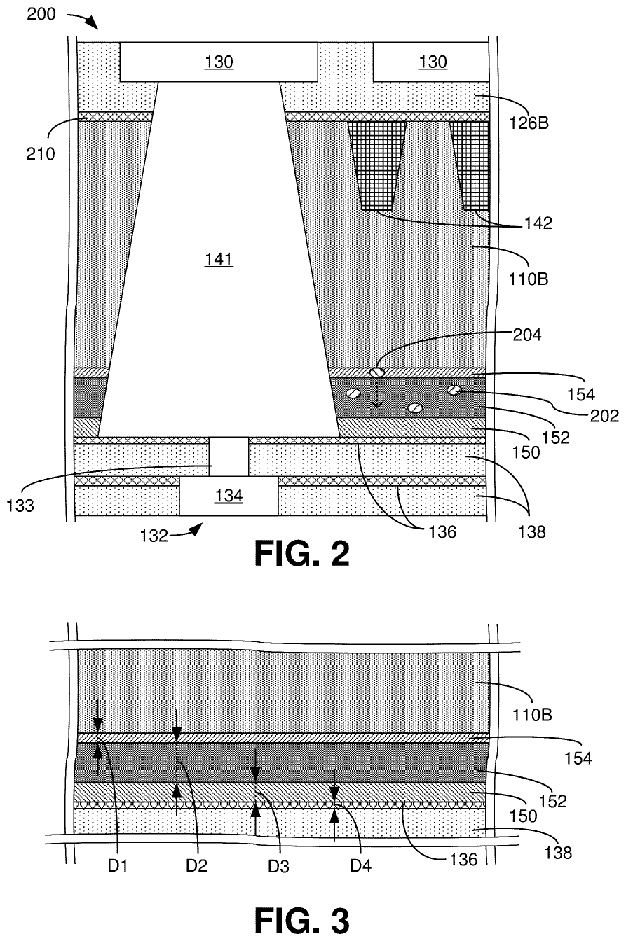

In some embodiments, one or more etch stop layers 136 may be disposed among dielectric layers 126A, dielectric layers 138, and other dielectric layers disclosed herein. Some examples of such etch stop layers 136 are depicted in FIG. 2, discussed below. Etch stop layers 136 may include one or more of silicon nitride (SiN), silicon carbide (SiC), silicon carbonitride (SiCN), and/or another dielectric material.

Continuing with FIG. 1, IC die 102 may include a semiconductor substrate 110B (e.g., including silicon (Si) or another semiconductor material) that includes a plurality of well regions 140. For example, well regions 140 may be ion-doped or implanted to become n-type or p-type well regions. Further, in some embodiments, one or more well regions 140 may include source-drain regions 129 disposed within well regions 140. For example, n-type well regions 140 may include p-type source-drain regions 129, and vice-versa. As employed herein, the term “source-drain region” or the like may refer to a source or drain, individually or collectively, depending upon the context.

In some embodiments, substrate 110B may include one or more shallow trench isolation (STI) structures 142 extending from an upper side of substrate 110B downward. In some embodiments, STI structures 142 may substantially isolate adjacent well regions 140. Also, in some embodiments, STI structures 142 may include silicon oxide (e.g., silicon dioxide (SiO₂)) or another dielectric material.

Disposed on an upper side of substrate 110B at each of one or more well regions 140 may be a gate structure 128. In some embodiments, gate structure 128 may include a layer of oxide or other dielectric material, on which may be disposed a conductive element. In such cases, gate structure 128 may operate as a gate terminal in conjunction with source-drain regions 129 and well region 140 to form a transistor that may be employed in a readout or processing circuit for image data originating from IC die 101.

Also disposed on an upper side of substrate 110B may be one or more dielectric layers 126B, with one or more conductive structures 130 disposed therein, in a manner similar to that described above in conjunction with IC die 101. In some embodiments, conductive structures 130 may be electrically connected to gate structures 128, source-drain regions 129, or other structures or elements within IC die 102.

Additionally, in some embodiments, one or more dielectric layers 138, possibly including one or more etch stop layers 136, may be disposed over dielectric layers 126B. Further, in dielectric layers 138, one or more conductive bonding structures 132 may be disposed, in a manner similar to that described above in connection with IC die 101. In some embodiments, one or more conductive bonding structures 132 may be coupled with one or more conductive structures 130 of IC die 102 and/or bonding structures 132 of IC die 101, thus facilitating electrical connections between IC dies 101 and 102 at a bonding region 104A.

In some embodiments, a plurality of dielectric layers 154, 152, and/or 150 may be disposed at a lower side of substrate 110B of IC die 102 (e.g., to provide a stable foundation on which dielectric layers 138 and accompanying conductive bond structures 132 may be disposed for bonding with IC die 103 at a bonding region 104B). Various characteristics of such dielectric layers 154, 152, and 150, and use thereof in conjunction with conductive bond structures 132, are described in greater detail below in conjunction with FIG. 2, which is a magnified cross-sectional view of a region 200 denoted in FIG. 1.

Additionally, in IC die 102, a through-substrate via (TSV) structure 141 may be disposed therein and extend from one or more of the plurality of dielectric layers disposed at the lower side of substrate 110B, through substrate 110B, and to at least one of the conductive structures 130 located in dielectric layers 126B. Further, in some embodiments, a lower end of TSV structure 141 may be electrically connected to one or more conductive bonding structures 132, thus facilitating an electrical connection between one or more conductive structures 130 of IC die 102 and IC die 103.

As depicted in FIG. 1, in some embodiments, IC die 103 may include a semiconductor substrate 110C in which well regions 140, source-drain regions 129, and STI structures 142 may be disposed, as discussed above in relation to IC die 102. Further, gate structures 128 may be disposed on well regions 140 of substrate 110C, and conductive structures 130 may be disposed within dielectric layers 126C, which in turn may be disposed on an upper side of substrate 110C, in a manner corresponding to that described above in conjunction with IC die 102. Further, bonding structures 132 may be disposed in dielectric layers 138, which may be disposed on dielectric layers 126C. Additionally in some embodiments, one or more etch stop layers 136 may be disposed among dielectric layers 138.

FIG. 2 illustrates a cross-sectional view of some embodiments of magnified region 200 of the cross-sectional view of FIG. 1, including a multiple-layer dielectric structure, having dielectric layers 154, 152, and 150, disposed on a lower side of substrate 110B. FIG. 2, for example, depicts STI structures 142 disposed within substrate 110B, an etch stop layer 210 disposed on the upper side of substrate 110B, and dielectric layer 126B disposed on etch stop layer 210.

Further, dielectric layers 154, 152, and 150 are disposed on the lower side of substrate 110B, and etch stop layers 136 and dielectric layers 138 are disposed in an interlaced arrangement on dielectric layer 152. In some embodiments, dielectric layer 154 disposed on substrate 110B may include a high-k dielectric layer, although other types of dielectric material may be employed in other embodiments. Dielectric layer 150 disposed on dielectric layer 152 may be a passivation layer or isolation barrier, and may include, but is not limited to, silicon nitride (SiN).

Dielectric layer 152, when fabricated, may produce less water vapor and nitrogen than at least some other dielectric layers disposed within an IC die. For example, dielectric layer 152 may be a high-density-plasma (HDP) oxide (e.g., a form of silicon dioxide (SiO₂)). In some embodiments, the HDP oxide may be deposited using an HPD CVD process that employs a combination of silane (SiH₄) gas and oxygen (O₂) gas (e.g., at approximately 300 degrees Celsius, or in a range between 275 degrees and 325 degrees Celsius). Also, argon (Ar) gas may be included as a carrier gas to create a high-density plasma that facilitates thin film deposition onto dielectric layer 154 by chemically reacting with the silane and oxygen.

In some examples, the use of the oxygen gas may result in the generation of significantly fewer nitrogen molecules or ions 202 disposed within dielectric layer 152 compared to that of other dielectric layers (e.g., those dielectric layers often deployed in a IMD layer or an inter-die bonding layer). Also, in some examples, the HPD CVD process (e.g., particularly at the approximately 300-degree temperature) may cause significant reduction in the amount of water vapor (H₂O) molecules 204 produced to create HDP oxide relative to the creation of other dielectric layers (e.g., USG or low-deposition-rate resistor protection oxide (LRPO)) using other processes. Further, in some examples, the reduced number of nitrogen molecules or ions 202 may limit repelling of water vapor molecules 204 toward the substrate 110B, thus reducing the possibility of a separation or delamination between substrate 110B and dielectric layer 154, thereby possibly increasing IC device 100 quality and reliability.

In contrast, use of another material for dielectric layer 152 (e.g., undoped silicate glass (USG)) may promote such delamination. For example, in another embodiment, USG may be deposited on dielectric layer 154 using an HPD CVD process that employs a combination of silane (SiH₄) gas (e.g., at any of various concentration levels) and nitrous oxide (N₂O) gas (e.g., at approximately 400 degrees Celsius). In some embodiment, argon (Ar) gas may be included as a carrier gas to create a high-density plasma that facilitates thin film deposition onto dielectric layer 154 by chemically reacting with the silane and nitrous oxide. In some examples, the use of the nitrous oxide may result in the generation of a significant number of nitrogen molecules or ions 202 (e.g., in the form of SiN-ions) disposed within dielectric layer 152. Also, such an HPD CVD process (e.g., particularly at the 400-degree temperature) may cause a significant amount of water vapor (H₂O) molecules 204 to be present. Further, in some examples, the presence of a relatively significant number of nitrogen molecules or ions 202, in turn, may repel water vapor molecules 204 toward the substrate 110B (e.g., as a result of heating during subsequent processing of IC device 100), some of which may ultimately reside at one or more portions of the interface of substrate 110B and dielectric layer 154, which may in turn cause a separation or delamination between substrate 110B and dielectric layer 154. Such delamination would result in reduced quality and reliability of IC device 100.

In further embodiments, with reference to FIG. 1, the one or more dielectric layers 126A, 126B, 126C, 138 of the IC dies 101, 102, 103 may include one or more individual dielectric layers including a first dielectric material (e.g., silicon dioxide, USG, etc.) doped or infused with nitrogen. The at least one individual dielectric layer may, for example, be an inter-layer dielectric (ILD) layer, an inter-metal dielectric (IMD) layer, a bonding dielectric layer, or the like. In various embodiments, a first atomic percentage of nitrogen in the one or more individual dielectric layers is within a range of about 15 at % to 30 at % or some other suitable value. In further embodiments, the at least one individual dielectric layer may be formed by an HPD CVD process that employs a combination of silane (SiH₄) gas and nitrous oxide (N₂O) gas (e.g., at approximately 400 degrees Celsius). In some embodiments, the dielectric layer 152 comprises the first dielectric material (e.g., silicon dioxide). In various embodiments, the dielectric layer 152 is doped or infused with nitrogen and has a second atomic percentage of nitrogen (e.g., about 0.5 at % or less, less than about 1.0 at %, etc.) that is less than the first atomic percentage of nitrogen of the one or more individual dielectric layers. In further embodiments, a concentration of nitrogen in the dielectric layer 152 is less than five percent of a concentration of nitrogen in the one or more individual dielectric layers. The dielectric layer 152 having a relatively low concentration of nitrogen (e.g., less than five percent of the concentration of nitrogen in the one or more individual dielectric layers) reduces or prevents separation or delamination between substrate 110B and dielectric layer 152, thereby increasing IC device 100 quality and reliability.

FIG. 3 illustrates a cross-sectional view depicting thicknesses of some embodiments of a subset of dielectric layers shown in FIG. 2. More specifically, dielectric layer 154 is shown with a thickness D1, dielectric layer 152 is shown with a thickness D2, dielectric layer 150 is shown with a thickness D3, and etch stop layer 136 is shown with a thickness D4. In some embodiments, etch stop layer 136 may be the narrowest of the four dielectric layers shown (e.g., D4<D3, D2, and D1). Further, in some embodiments, the thickness of dielectric layer 154 (e.g., when including a high-k dielectric material) may be significantly less than that of dielectric layers 152 and 150 (e.g., D1<D2 and D3). Moreover, in some embodiments, the thickness of dielectric layer 152 (e.g., an HDP oxide) may be significantly greater than that of dielectric layer 150 (e.g., D2>D3). In some embodiments, the thickness D1 of the dielectric layer 154 is within a range of about 500 angstroms (Å) to 700 Å, or some other suitable value. In some embodiments, the thickness D2 of the dielectric layer 152 is within a range of about 2000 Å to 7500 Å, or some other suitable value. In some embodiments, the thickness D3 of the dielectric layer 150 is within a range of about 1500 Å to 2000 Å, or some other suitable value.

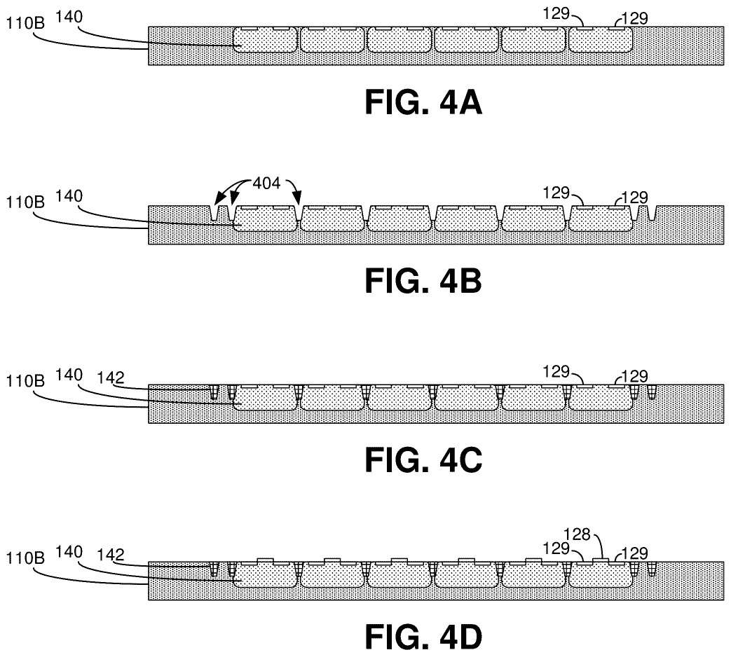

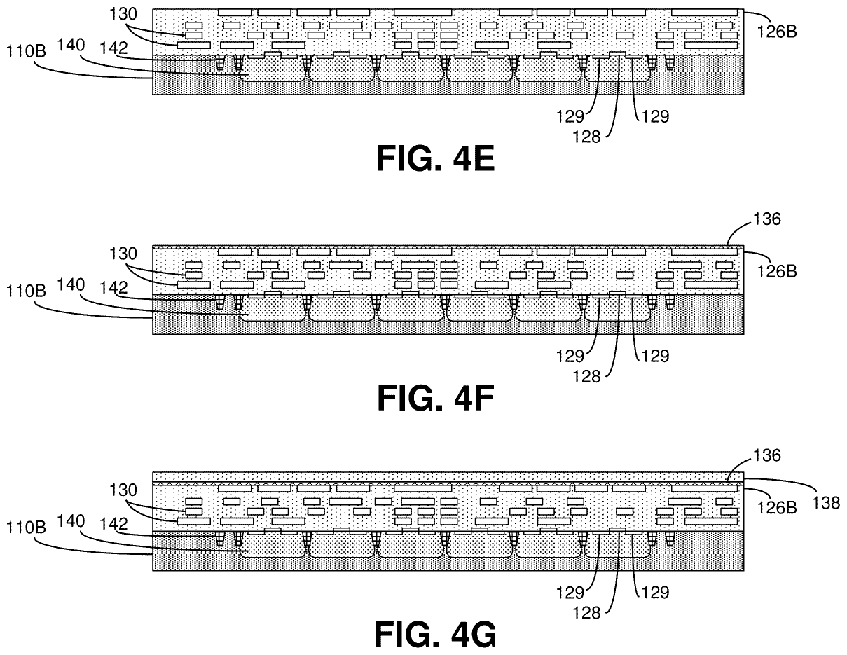

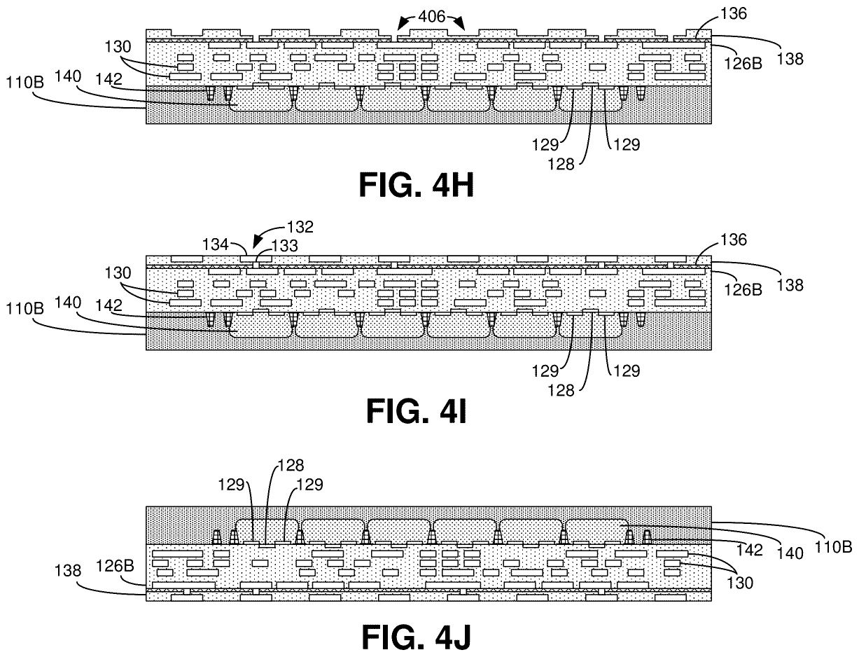

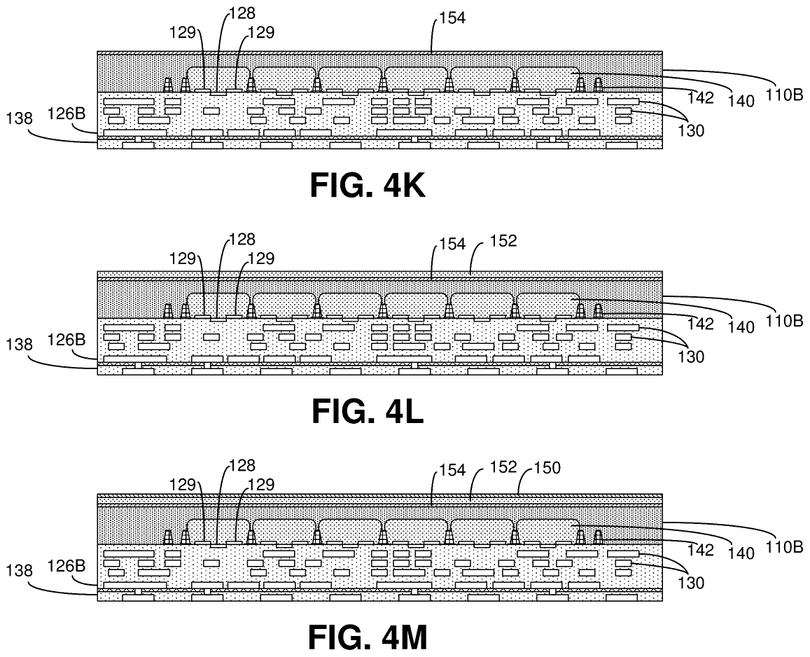

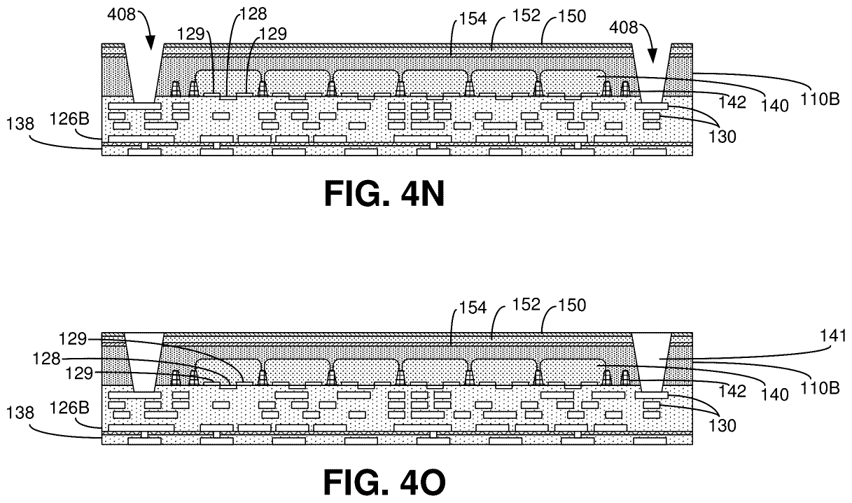

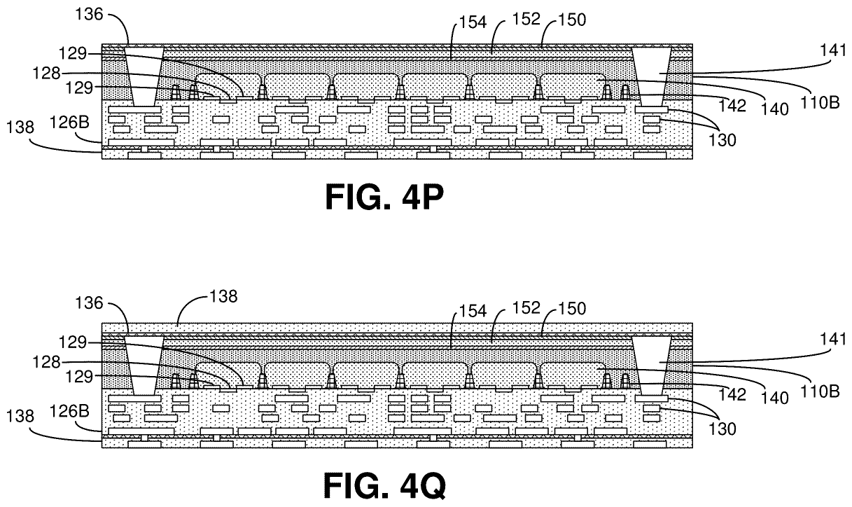

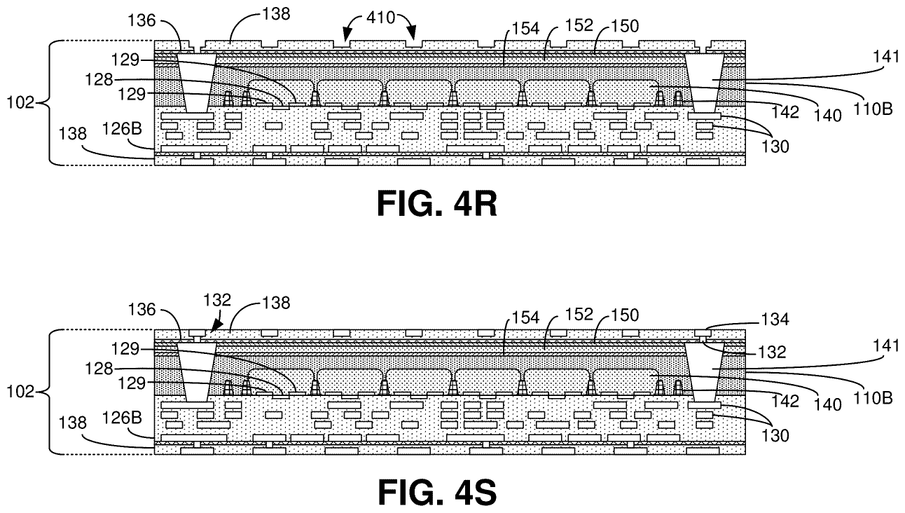

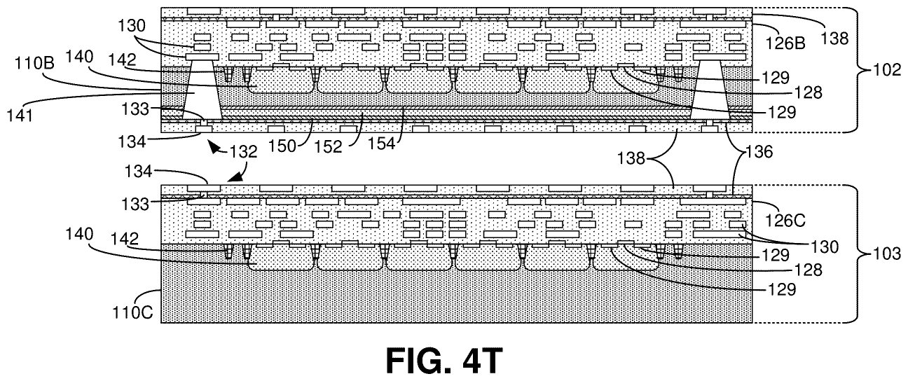

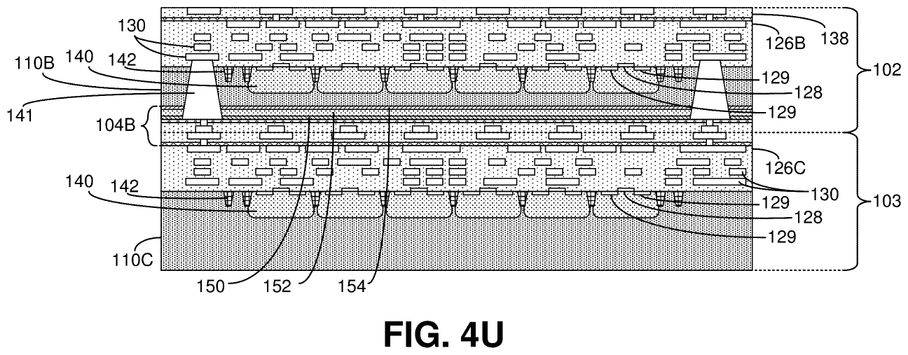

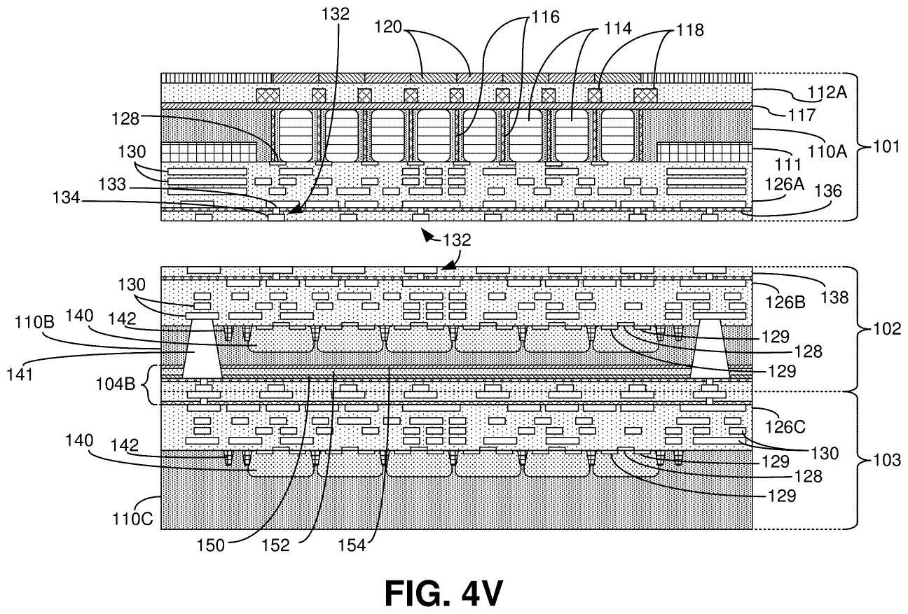

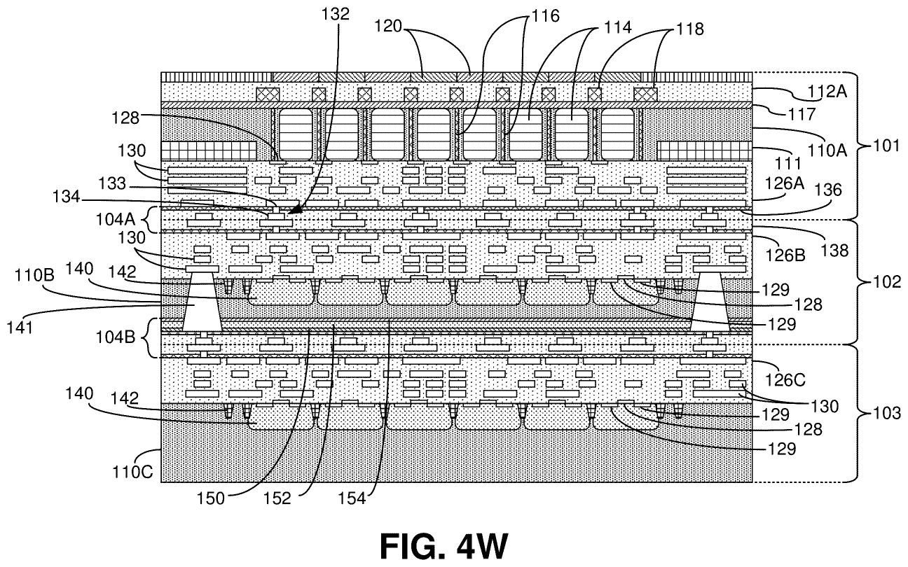

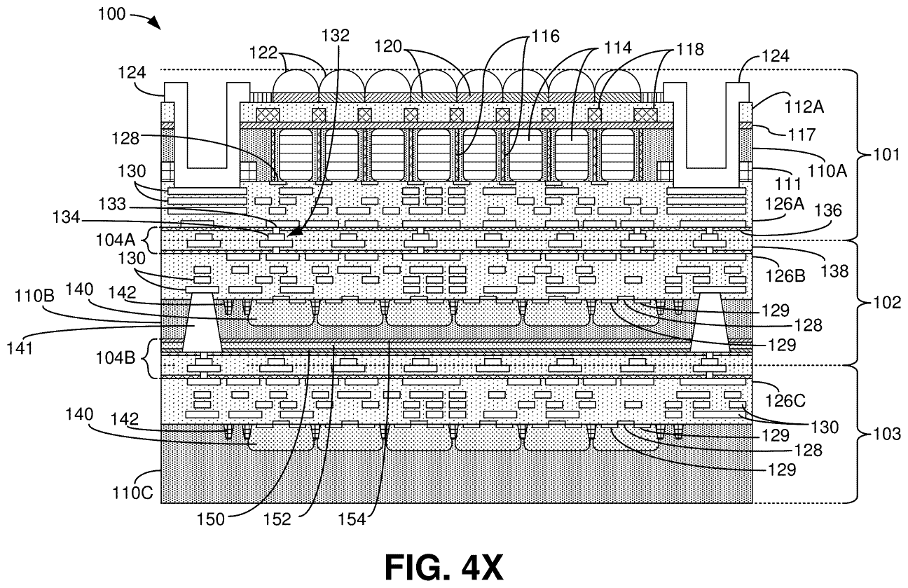

FIGS. 4A through 4X illustrate cross-sectional views of some embodiments of a multiple-die IC device (e.g., IC device 100 of FIG. 1) at various stages of manufacture, according to the present disclosure. Although FIGS. 4A through 4X are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part.

For example, FIG. 4A illustrates the forming (e.g., by way of doping, implantation, or the like) of at least one well region 140 within a substrate 110B for IC die 102. Further, within each one or more of the at least one well region 140, one or more source-drain regions 129 may be formed.

FIG. 4B illustrates the removing (e.g., by way of lithography and etching) of portions of substrate 110B to form one or more trenches 404 (e.g., between adjacent well regions 140 and/or other locations along an upper side of substrate 110B). FIG. 4C illustrates the forming (e.g., deposition) of dielectric material in trenches 404 to form shallow trench isolation (STI) structures 142. In some embodiments, STI structures 142 may include, but are not limited to, silicon oxide (e.g., silicon dioxide (SiO₂)) or another dielectric material. In some embodiments, a chemical-mechanical planarization (CMP) operation may follow the forming of STI structures 142.

FIG. 4D illustrates the forming (e.g., deposition and subsequent lithography and etching) of gate structures 128 (e.g., one gate structure 128 for each well region 140) on substrate 110B. In some embodiments, gate structures 128 may include, but are not limited to, polycrystalline silicon (poly-Si) or another conductive material.

FIG. 4E illustrates the forming of one or more conductive structures 130 within at least one dielectric layers 126B formed on substrate 110B. In some embodiments, such forming may include deposition of one or more dielectric layers 126B, interspersed with photolithography and etching of dielectric layers 126B and subsequent deposition of conductive material to form portions of conductive structures 130, which may include conductive elements interconnected with conductive via structures (not explicitly shown in FIG. 4E). In some embodiments, the dielectric material may include, but is not limited to, silicon oxide (SiOx) (e.g., silicon oxide (SiO₂)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like. Also, in some embodiments, the conductive material may include copper (Cu) or another metal, alloy, and/or other conductive material. In addition, in some embodiments, one or more etch stop layers (not illustrated in FIG. 4E) may be formed between some dielectric layers 126B.

FIG. 4F illustrates the forming (e.g., deposition) of an etch stop layer 136 on a dielectric layer 126B, and possibly one or more conductive elements of conductive structures 130. In some embodiments, etch stop layer 136 may include, but is not limited to, silicon nitride (SiN), silicon carbide (SiC), silicon carbonitride (SiCN), and/or another dielectric material.

FIG. 4G illustrates the forming (e.g., deposition) of a dielectric layer 138 on etch stop layer 136. In some embodiments, dielectric layer 138 may include one or more dielectric materials described above.

FIG. 4H illustrates the removal (e.g., by way of photolithography and etching) of portions of dielectric layer 138 to form one or more trenches 406. Thereafter, FIG. 4I illustrates the forming (e.g., deposition) of one or more conductive bonding structures 132 (e.g., including bonding elements 134 and possibly bonding via elements 133, each connecting a corresponding bonding element 134 to one or more conductive structures 130). In some embodiments, conductive bonding structures 132 may include copper (Cu) or another metal, alloy, and/or other conductive material. Moreover, in some embodiments, a CMP operation may be performed on the resulting surface of dielectric layer 138 and conductive bonding structures 132.

FIG. 4J illustrates the inversion or “flipping” of the structure of FIG. 4I to facilitate the forming of structures on the lower side of substrate 110B, such as the various dielectric structures discussed above in connection with FIG. 2.

FIG. 4K illustrates the forming (e.g., deposition) of a dielectric layer 154 on substrate 110B. In some embodiments, dielectric layer 154 may include, but is not limited to, a high-k dielectric layer or another dielectric material.

FIG. 4L illustrates the forming (e.g., deposition) of a dielectric layer 152 on dielectric layer 154. In some embodiments, dielectric layer 152 may include an HDP oxide. More specifically, in some embodiments, the forming of dielectric layer 152 may be performed using an HDP CVD process employing a combination of silane gas and oxygen gas (e.g., at approximately 300 degrees Celsius, or in a range between 275 degrees and 325 degrees Celsius).

FIG. 4M illustrates the forming (e.g., deposition) of a dielectric layer 150 on dielectric layer 152. In some embodiments, dielectric layer 150 may be a passivation layer and/or isolation barrier, and may include, but is not limited to, silicon nitride (SiN).

FIG. 4N illustrates the removal (e.g., by lithography and etching) of material to form one or more trenches 408 through dielectric layers 150, 152, and 154, through substrate 110B, and into dielectric layer 126B, ending at a conductive structure 130. Thereafter, FIG. 40 illustrates the forming (e.g., deposition) of a conductive material (e.g., copper (Cu) or another metal, alloy, or other conductive material) to form one or more TSV structures 141.

FIG. 4P illustrates the forming (e.g., deposition) of an etch stop layer 136 on dielectric layer 150 and TSV structures 141. FIG. 4Q illustrates the subsequent forming (e.g., deposition) of a dielectric layer 138 on etch stop layer 136.

FIG. 4R illustrates the removal (e.g., by way of photolithography and etching) of one or more portions of dielectric material to form one or more trenches 410 (e.g., at least partially into dielectric layer 138, and possibly through dielectric layer 138 and etch stop layer 136 to a TSV structure 141). FIG. 4S illustrates the forming (e.g., deposition) of conductive material to provide conductive bonding structures 132 in a manner similar to that described above in conjunction with FIG. 4I, resulting in the formation of IC die 102. Moreover, in some embodiments, a CMP operation may be performed on the resulting surface of dielectric layer 138 and conductive bonding structures 132.

FIG. 4T illustrates the inversion of IC die 102 in preparation for bonding with IC die 103. In some embodiments, various layers and structures of IC die 103 are disposed as described above in conjunction with FIG. 1. Thereafter, FIG. 4U illustrates the bonding of IC dies 102 and 103 to create electrical connections therebetween by way of bonding structures 132 in a bonding region 104B. In some embodiments, the bonding may be a heat-based bonding, in which IC dies 102 and 103 are brought into contact (e.g., at room temperature) with each other to bond the facing dielectric layers 138. The assembly may then be heated to urge opposing conductive bonding structures 132 together in bonding region 104B.

FIG. 4V illustrates the positioning of IC die 101 such that dielectric layers 138 and conductive bonding structures 132 of IC dies 101 and 102 face each other. Thereafter, FIG. 4W illustrates the bonding of IC dies 102 and 103 to create electrical connections therebetween by way of bonding structures 132 in bonding region 104A. In some embodiments, the bonding may be a heat-based bonding, as described above in connection with FIG. 4U.

FIG. 4X illustrates further processing of IC die 101 to create IC device 100. In some embodiments, such processing may include the forming of trenches (e.g., by way of photolithography and etching) extending from an upper side of IC die 101 downward to at least one conductive structure 130, forming (e.g., by way of conformal deposition) upper bond structures 124 in the trenches, and forming (e.g., by way of deposition and etching) of lenses 122 on filter elements 120.

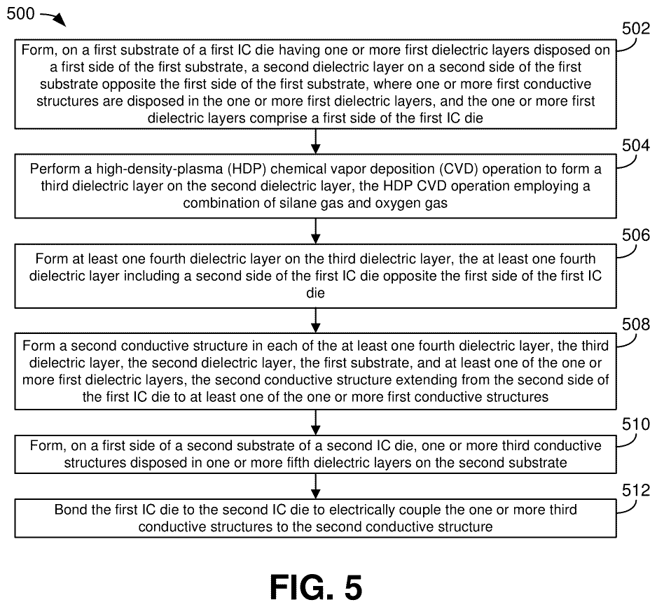

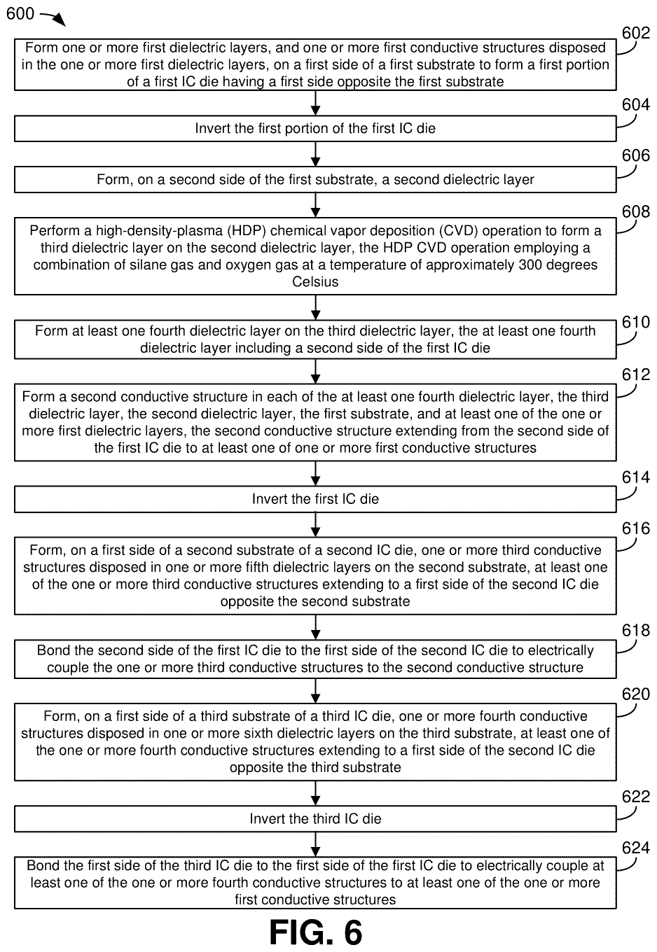

FIGS. 5 and 6 illustrate methodologies 500 and 600, respectively, of forming a multiple-die IC device (e.g., IC device 100), in accordance with some embodiments of the present disclosure. Although these methods and others illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 502, on a first substrate (e.g., substrate 110B of FIG. 1) of a first IC die (e.g., IC die 102 of FIG. 1) having one or more first dielectric layers (e.g., dielectric layers 126B of FIG. 1) disposed on a first side of the first substrate, a second dielectric layer (e.g., dielectric layer 154 of FIGS. 1 and 2) formed on a second side of the first substrate opposite the first side of the first substrate, where one or more first conductive structures (e.g., conductive structures 130 of FIG. 1) are disposed in the one or more first dielectric layers. FIG. 4K illustrates a cross-sectional view of some embodiments corresponding to Act 502.

At Act 504, a high-density-plasma (HDP) chemical vapor deposition (CVD) operation is performed to form a third dielectric layer (e.g., dielectric layer 152 of FIGS. 1 and 2) on the second dielectric layer. The HDP CVD operation employs a combination of silane gas and oxygen gas. FIG. 4L illustrates a cross-sectional view of some embodiments corresponding to Act 504.

At Act 506, at least one fourth dielectric layer (e.g., dielectric layers 150 and 138 of FIGS. 1 and 2) is formed on the third dielectric layer. The at least one fourth dielectric layer includes a second side of the first IC die. FIG. 4M illustrates a cross-sectional view of some embodiments corresponding to Act 506.

At Act 508, a second conductive structure (e.g., TSV structure 141 and conductive bonding structure 132 of FIGS. 1 and 2) is formed in each of the at least one fourth dielectric layer, the third dielectric layer, the second dielectric layer, the first substrate, and at least one of the one or more first dielectric layers. The second conductive structure extends from the second side of the first IC die to at least one of the one or more first conductive structures. FIGS. 4N through 4S illustrate cross-sectional views of some embodiments corresponding to Act 508.

At Act 510, on a first side of a second substrate of a second IC die, one or more third conductive structures (e.g., conductive structure 130 and conductive bonding structure 132 of FIG. 1) disposed in one or more fifth dielectric layers (e.g., dielectric layers 126C and 138 of FIG. 1) are formed on the second substrate. FIG. 4T illustrates a cross-sectional view of some embodiments corresponding to Act 510.

At Act 512, the first IC die is bonded to the second IC die to electrically couple the one or more third conductive structures to the second conductive structure. FIG. 4U illustrates a cross-sectional view of some embodiments corresponding to Act 512.

With respect to methodology 600 of FIG. 6, at Act 602, one or more first dielectric layers (e.g., dielectric layers 126B and 138 of FIG. 1), and one or more first conductive structures (e.g., conductive structures 130 and conductive bonding structures 132 of FIG. 1) disposed in the one or more first dielectric layers, are formed on a first side of a first substrate (e.g., substrate 110B of FIG. 1) to form a first portion of a first IC die (e.g., IC die 102) having a first side opposite the first substrate. FIGS. 4E through 4I illustrate cross-sectional views of some embodiments corresponding to Act 602.

At Act 604, the first portion of the first IC die is inverted. FIG. 4J illustrates a cross-sectional view of some embodiments corresponding to Act 604.

At Act 606, a second dielectric layer (e.g., dielectric layer 154 of FIGS. 1 and 2) is formed on a second side of the first substrate. FIG. 4K illustrates a cross-sectional view of some embodiments corresponding to Act 606.

At Act 608, a high-density-plasma (HDP) chemical vapor deposition (CVD) operation is performed to form a third dielectric layer (e.g., dielectric layer 152 of FIGS. 1 and 2) on the second dielectric layer. The HDP CVD operation may employ a combination of silane gas and oxygen gas at a temperature of approximately 300 degrees Celsius. FIG. 4L illustrates a cross-sectional view of some embodiments corresponding to Act 608.

At Act 610, at least one fourth dielectric layer (e.g., dielectric layers 150 and 138 of FIGS. 1 and 2) is formed on the third dielectric layer. The at least one fourth dielectric layer may include a second side of the first IC die. FIGS. 4M through 4Q illustrate cross-sectional views of some embodiments corresponding to Act 610.

At Act 612, a second conductive structure (e.g., TSV structure 141 and conductive bonding structure 132 of FIGS. 1 and 2) is formed in each of the at least one fourth dielectric layer, the third dielectric layer, the second dielectric layer, the first substrate, and at least one of the one or more first dielectric layers. The second conductive structure may extend from the second side of the first IC die to at least one of one or more first conductive structures. FIGS. 4N through 4S illustrate cross-sectional views of some embodiments corresponding to Act 612.

At Act 614, the first IC die is inverted. FIG. 4T illustrates a cross-sectional view of some embodiments corresponding to Act 614.

At Act 616, on a first side of a second substrate (e.g., substrate 110C of FIG. 1) of a second IC die (e.g., IC die 103 of FIG. 1), one or more third conductive structures (e.g., conductive structures 130 and conductive bonding structures 132 of FIG. 1) disposed in one or more fifth dielectric layers (e.g., dielectric layers 126C and 138 of FIG. 1) are formed on the second substrate. At least one of the one or more third conductive structures may extend to a first side of the second IC die opposite the second substrate. FIG. 4T illustrates a cross-sectional view of some embodiments corresponding to Act 616.

At Act 618, the second side of the first IC die is bonded to the first side of the second IC die to electrically couple the one or more third conductive structures to the second conductive structure. FIG. 4U illustrates a cross-sectional view of some embodiments corresponding to Act 618.

At Act 620, on a first side of a third substrate (e.g., substrate 110A of FIG. 1) of a third IC die (e.g., IC die 101 of FIG. 1), one or more fourth conductive structures (e.g., conductive structures 130 and conductive bonding structures 132 of FIG. 1) disposed in one or more sixth dielectric layers (e.g., dielectric layers 126A and 138 of FIG. 1) are formed on the third substrate. At least one of the one or more fourth conductive structures may extend to a first side of the second IC die opposite the third substrate. FIG. 4V illustrates a cross-sectional view of some embodiments corresponding to Act 620.

At Act 622, the third IC die is inverted. FIG. 4V illustrates a cross-sectional view of some embodiments corresponding to Act 622.

At Act 624, the first side of the third IC die is bonded to a first side of the first IC die to electrically couple at least one of the one or more fourth conductive structures to at least one of the one or more first conductive structures. FIG. 4W illustrates a cross-sectional view of some embodiments corresponding to Act 624.

Accordingly, in some embodiments, the present disclosure relates to a method. The method includes forming, on a first substrate of a first IC die having one or more first dielectric layers disposed on a first side of the first substrate, a second dielectric layer on a second side of the first substrate opposite the first side of the first substrate, where one or more first conductive structures are disposed in the one or more first dielectric layers, and the one or more first dielectric layers comprise a first side of the first IC die; performing a high-density-plasma (HDP) chemical vapor deposition (CVD) operation to form a third dielectric layer on the second dielectric layer, the HDP CVD operation employing a combination of silane (SiO₄) gas and oxygen (O₂) gas; forming at least one fourth dielectric layer on the third dielectric layer, the at least one fourth dielectric layer including a second side of the first IC die opposite the first side of the first IC die; forming a second conductive structure in each of the at least one fourth dielectric layer, the third dielectric layer, the second dielectric layer, the first substrate, and at least one of the one or more first dielectric layers, the second conductive structure extending from the second side of the first IC die to at least one of the one or more first conductive structures; forming, on a first side of a second substrate of a second IC die, one or more third conductive structures disposed in one or more fifth dielectric layers on the second substrate; and bonding the first IC die to the second IC die to electrically couple the one or more third conductive structures to the second conductive structure.

In other embodiments, the present disclosure relates to another method. The method includes forming one or more first dielectric layers, and one or more first conductive structures disposed in the one or more first dielectric layers, on a first side of a first substrate to form a first portion of a first IC die having a first side opposite the first substrate; inverting the first portion of the first IC die; forming, on a second side of the first substrate, a second dielectric layer; performing a high-density-plasma (HDP) chemical vapor deposition (CVD) operation to form a third dielectric layer on the second dielectric layer, the HDP CVD operation employing a combination of silane (SiO₄) gas and oxygen (O₂) gas at a temperature of approximately 300 degrees Celsius; forming at least one fourth dielectric layer on the third dielectric layer, the at least one fourth dielectric layer including a second side of the first IC die; forming a second conductive structure in each of the at least one fourth dielectric layer, the third dielectric layer, the second dielectric layer, the first substrate, and at least one of the one or more first dielectric layers, the second conductive structure extending from the second side of the first IC die to at least one of one or more first conductive structures; inverting the first IC die; forming, on a first side of a second substrate of a second IC die, one or more third conductive structures disposed in one or more fifth dielectric layers on the second substrate, at least one of the one or more third conductive structures extending to a first side of the second IC die opposite the second substrate; bonding the second side of the first IC die to the first side of the second IC die to electrically couple the one or more third conductive structures to the second conductive structure; forming, on a first side of a third substrate of a third IC die, one or more fourth conductive structures disposed in one or more sixth dielectric layers on the third substrate, at least one of the one or more fourth conductive structures extending to a first side of the second IC die opposite the third substrate; inverting the third IC die; and bonding the first side of the third IC die to the first side of the first IC die to electrically couple at least one of the one or more fourth conductive structures to at least one of the one or more first conductive structures.

In yet other embodiments, the present disclosure relates to an IC device. The IC device includes a first IC die including: a first substrate; one or more first dielectric layers disposed on an upper side of the first substrate; one or more first conductive structures disposed in the one or more first dielectric layers; a second dielectric layer disposed on a lower side of the first substrate; a third dielectric layer disposed on a lower side of the second dielectric layer, the third dielectric layer having a nitrogen concentration that is less than five percent of a nitrogen concentration of at least one of the one or more first dielectric layers; at least one fourth dielectric layer disposed on a lower side of the third dielectric layer, the at least one fourth dielectric layer including a lower side of the first IC die; and a second conductive structure extending from the lower side of the first IC die upward through the first substrate to at least one of the one or more first conductive structures; and a second IC die including: a second substrate; one or more fifth dielectric layers disposed on an upper side of the second substrate; and one or more third conductive structures disposed in the one or more fifth dielectric layers, where at least one of the one or more third conductive structures is electrically coupled to the second conductive structure at an upper side of the second IC die.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming, on a first substrate of a first IC die having one or more first dielectric layers disposed on a first side of the first substrate, a second dielectric layer on a second side of the first substrate opposite the first side of the first substrate, wherein one or more first conductive structures are disposed in the one or more first dielectric layers, and the one or more first dielectric layers comprise a first side of the first IC die;
performing a high-density-plasma (HDP) chemical vapor deposition (CVD) operation to form a third dielectric layer on the second dielectric layer, the HDP CVD operation employing a combination of silane (SiO₄) gas and oxygen (O₂) gas;
forming at least one fourth dielectric layer on the third dielectric layer, the at least one fourth dielectric layer comprising a second side of the first IC die opposite the first side of the first IC die;
forming a second conductive structure in each of the at least one fourth dielectric layer, the third dielectric layer, the second dielectric layer, the first substrate, and at least one of the one or more first dielectric layers, the second conductive structure extending from the second side of the first IC die to at least one of the one or more first conductive structures;
forming, on a first side of a second substrate of a second IC die, one or more third conductive structures disposed in one or more fifth dielectric layers on the second substrate; and
bonding the first IC die to the second IC die to electrically couple the one or more third conductive structures to the second conductive structure.

2. The method of claim 1, wherein the HDP CVD operation is performed at a temperature of approximately 300 degrees Celsius.

3. The method of claim 1, wherein the second dielectric layer comprises a high-k dielectric material.

4. The method of claim 1, wherein the third dielectric layer comprises silicon dioxide.

5. The method of claim 1, wherein the second conductive structure comprises:
a conductive through-substrate via (TSV) structure extending through the first substrate to the at least one of the one or more first conductive structures; and
a first conductive bonding structure disposed on the conductive TSV structure and extending to the second side of the first IC die.

6. The method of claim 5, wherein:
the one or more third conductive structures comprises a second conductive bonding structure forming a portion of a first side of the second IC die; and
bonding the first IC die to the second IC die comprises electrically coupling the second conductive bonding structure to the first conductive bonding structure.

7. A method, comprising:
forming one or more first dielectric layers, and one or more first conductive structures disposed in the one or more first dielectric layers, on a first side of a first substrate to form a first portion of a first IC die having a first side opposite the first substrate;
inverting the first portion of the first IC die;
forming, on a second side of the first substrate, a second dielectric layer;
performing a high-density-plasma (HDP) chemical vapor deposition (CVD) operation to form a third dielectric layer on the second dielectric layer, the HDP CVD operation employing a combination of silane (SiO₄) gas and oxygen (O₂) gas at a temperature of approximately 300 degrees Celsius;
forming at least one fourth dielectric layer on the third dielectric layer, the at least one fourth dielectric layer comprising a second side of the first IC die;
forming a second conductive structure in each of the at least one fourth dielectric layer, the third dielectric layer, the second dielectric layer, the first substrate, and at least one of the one or more first dielectric layers, the second conductive structure extending from the second side of the first IC die to at least one of the one or more first conductive structures;
inverting the first IC die;
forming, on a first side of a second substrate of a second IC die, one or more third conductive structures disposed in one or more fifth dielectric layers on the second substrate, at least one of the one or more third conductive structures extending to a first side of the second IC die opposite the second substrate;
bonding the second side of the first IC die to the first side of the second IC die to electrically couple the one or more third conductive structures to the second conductive structure;
forming, on a first side of a third substrate of a third IC die, one or more fourth conductive structures disposed in one or more sixth dielectric layers on the third substrate, at least one of the one or more fourth conductive structures extending to a first side of the third IC die opposite the third substrate;
inverting the third IC die; and
bonding the first side of the third IC die to the first side of the first IC die to electrically couple at least one of the one or more fourth conductive structures to at least one of the one or more first conductive structures.

8. The method of claim 7, further comprising:
forming a photosensitive region in the third substrate; and
forming a gate structure on the first side of the third substrate proximate the photosensitive region, wherein at least one of the one or more fourth conductive structures is formed to be electrically connected to the gate structure.

9. The method of claim 7, further comprising:
forming an optical filter layer over the first side of the third substrate; and
forming a lens structure on the optical filter layer.

10. The method of claim 7, further comprising:
removing a portion of the third substrate by way of the second side of the third substrate to form a trench extending to one of the one or more fourth conductive structures; and
conformally forming an upper bond structure in the trench that is electrically coupled to the one of the one or more fourth conductive structures.

11. An integrated circuit (IC) device, comprising:
a first IC die comprising:
a first substrate;
one or more first dielectric layers disposed on an upper side of the first substrate;
one or more first conductive structures disposed in the one or more first dielectric layers;
a second dielectric layer disposed on a lower side of the first substrate;
a third dielectric layer disposed on a lower side of the second dielectric layer, the third dielectric layer having a nitrogen concentration that is less than five percent of a nitrogen concentration of at least one of the one or more first dielectric layers;
at least one fourth dielectric layer disposed on a lower side of the third dielectric layer, the at least one fourth dielectric layer comprising a lower side of the first IC die; and
a second conductive structure extending from the lower side of the first IC die upward through the first substrate to at least one of the one or more first conductive structures; and
a second IC die comprising:
a second substrate;
one or more fifth dielectric layers disposed on an upper side of the second substrate; and
one or more third conductive structures disposed in the one or more fifth dielectric layers, wherein at least one of the one or more third conductive structures is electrically coupled to the second conductive structure at an upper side of the second IC die.

12. The IC device of claim 11, wherein the third dielectric layer comprises a high-density-plasma (HDP) oxide formed by way of an HDP chemical vapor deposition (CVD) operation using a combination of silane (SiO₄) gas and oxygen (O₂) gas.

13. The IC device of claim 12, wherein the HDP CVD operation is performed at a temperature of approximately 300 degrees Celsius.

14. The IC device of claim 11, the second dielectric layer comprising a high-k dielectric material.

15. The IC device of claim 11, the second conductive structure comprising:
a conductive through-substrate via (TSV) structure extending upward through the first substrate to the at least one of the one or more first conductive structures; and
a first conductive bonding structure disposed on a lower end of the conductive TSV structure and extending downward to the lower side of the first IC die.

16. The IC device of claim 15, wherein the at least one of the one or more first conductive structures comprises a conductive element having a lower side that is electrically coupled to an upper end of the conductive TSV structure.

17. The IC device of claim 15, wherein:
the at least one of the one or more third conductive structures further comprises a second conductive bonding structure at the upper side of the second IC die; and
the second conductive bonding structure is electrically coupled to the first conductive bonding structure.

18. The IC device of claim 11, further comprising a third IC die comprising:
a third substrate;
one or more sixth dielectric layers disposed on an lower side of the third substrate; and
one or more fourth conductive structures disposed in the one or more sixth dielectric layers, wherein at least one of the one or more fourth conductive structures is electrically coupled to the at least one of the one or more first conductive structures.

19. The IC device of claim 18, wherein:
the at least one of the one or more first conductive structures comprises a first conductive bonding structure at an upper side of the first IC die;
the at least one of the one or more fourth conductive structures comprises a second conductive bonding structure at a lower side of the third IC die; and
the second conductive bonding structure is electrically coupled to the first conductive bonding structure.

20. The IC device of claim 18, wherein:
the third substrate comprises a photosensitive region;
at least one of the one or more fourth conductive structures is electrically coupled to a gate structure disposed on the third substrate proximate the photosensitive region.
